(19) United States
(12) Patent Application Publication
(10) Pub. No.: US 2025/0020752 A1
(43) Pub. Date: Jan. 16, 2025

(54) CALIBRATION METHOD FOR CALIBRATING A MEASUREMENT SYSTEM

(71) Applicant: Rohde & Schwarz GmbH & Co. KG, Muenchen (DE)

(72) Inventor: Julius SEEGER, Muenchen (DE)

(21) Appl. No.: 18/767,028

(22) Filed: Jul. 9, 2024

(30) Foreign Application Priority Data
Jul. 11, 2023 (DE) 10 2023 118 338.9

(51) Int. Cl. G01R 35/00; H04B 10/071; H04B 10/50

(52) U.S. Cl. CPC G01R 35/005; H04B 10/071; H04B 10/505

(57) ABSTRACT

A calibration method for calibrating a measurement system is described. The measurement system includes a conversion module, an electrical transmission module and an electrical reception module. The calibration method the includes measuring scattering parameters (S-parameters) of the electro-optical device or the opto-electrical device, wherein the measured S-parameters include at least one transmission coefficient in forward direction and two reflection coefficients; and determining actual S-parameters of the electro-optical device or the opto-electrical device based on the measured S-parameters. The actual S-parameters are determined taking a non-zero electrical output or input matching of the conversion module into account.

### FIELD OF THE DISCLOSURE

The disclosure relates to a calibration method for calibrating a measurement system for measurements on an electro-optical device which is set up to convert electrical signals into optical signals, or on an opto-electrical device which is set up to convert optical signals into electrical signals. The disclosure further relates to a measurement system for measurements on an electro-optical device or an opto-electrical device.

### BACKGROUND

With increasing demands on the data rate of data networks, optical channels are increasingly used for data transmission.

An appropriate electro-optical converter for example converts an electrical data signal into an optical data signal, which permits data transmission with a high bandwidth and small losses to the destination.

At the destination, for example a household, the optical data signal is reconverted into an electrical data signal by means of an opto-electrical converter.

Testing such opto-electrical or electro-optical devices using a measurement instrument requires an additional conversion module, as conventional measurement instruments are only limited to the measurement of electrical signals.

However, the additional conversion module also leads to additional calibration effort, as the conversion module may generate measurement errors which are to be compensated for by calibration.

Therefore, there is a need to provide a calibration method for calibrating a measurement system, which permits accurate measurements with the least possible calibration effort.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a calibration method for calibrating a measurement system for measurements on an electro-optical device which is set up to convert electrical signals into optical signals, or on an opto-electrical device which is set up to convert optical signals into electrical signals. The measurement system includes a conversion module, wherein the conversion module is set up to convert optical signals into electrical signals, or electrical signals into optical signals. The measurement system further includes an electrical transmission module and an electrical reception module. The calibration method comprises the following steps:
measuring scattering parameters (S-parameters) of the electro-optical device or the opto-electrical device, wherein the measured S-parameters comprise at least one transmission coefficient in forward direction and two reflection coefficients; and
determining actual S-parameters of the electro-optical device or the opto-electrical device based on the measured S-parameters.

The actual S-parameters are determined taking a non-zero electrical output or input matching of the conversion module into account. For the determination of the actual S-parameters, it is assumed that converting components only allow a forward transmission. For the determination of the actual S-parameters, it is further assumed that an actual reflection coefficient of the electro-optical device or the opto-electrical device in the optical range is equal to zero, and/or that an actual reflection coefficient of the conversion module in the optical range is equal to zero.

When testing an electro-optical device, the non-zero output matching of the conversion module is thus taken into account, which is also referred to as source port matching.

When testing an opto-electrical device, the non-zero input matching of the conversion module is taken into account, which is also referred to as directivity.

According to the disclosure, the measured S-parameters are corrected with respect to certain error terms of the transmission module, the reception module and the conversion module, so that the actual S-parameters can be determined with high accuracy.

This correction with respect to the error terms corresponds to a calibration of the measurement system.

It has been found that the actual S-parameters can be determined more precisely by taking the non-zero directivity or source port matching of the conversion module into account.

The directivity or source port matching of the conversion module corresponds to a reflection coefficient of the conversion module in the electrical range.

According to the disclosure, the calibration can furthermore be performed in a particularly time-efficient and resource-saving manner by simplifying assumptions.

It is assumed that the converting components, i.e. the conversion module and the electro-optical device or the opto-electrical device, only allow a forward transmission.

Generally, the converting components are not reciprocal. For example, a component converting an electrical signal into an optical signal (for example a Mach-Zehnder modulator) cannot convert an optical signal into an electrical signal. The accuracy of the determined actual S-parameters is therefore only insignificantly or even not at all influenced by this assumption.

It is furthermore assumed that an actual reflection coefficient of the conversion module in the optical range is equal to zero, and/or that an actual reflection coefficient of the electro-optical device or the opto-electrical device in the optical range is equal to zero.

This corresponds to the assumption that the impedance matching of the components in the optical range is substantially optimal, in particular optimal.

This assumption reduces the number of error terms to be taken into account, as a result of which the calibration can be carried out in a particularly time-efficient and resource-saving manner.

According to one aspect of the disclosure, the actual S-parameters are determined based on a transmission characteristic of the conversion module. In general terms, the transmission characteristic of the conversion module describes a relation between an input signal of the conversion module (i.e. an electrical signal or an optical signal) and an output signal of the conversion module (i.e. a corresponding optical signal or electrical signal). The accuracy of the determined actual S-parameters can be further increased by taking the transmission characteristic of the conversion module into account.

Typically, the transmission characteristic of the conversion module is independent of the test setup.

It is therefore conceivable that the transmission characteristic is determined by the manufacturer, for example in the context of a calibration of the conversion module during manufacture.

The transmission characteristic can accordingly be stored in a data storage device of the measurement system, in particular of the conversion module, and can be used without additional effort for calibrating the measurement system, particularly for determining the actual S-parameters.

It is however also possible for the transmission characteristic to be determined, in particular re-determined by a user of the measurement system.

In one embodiment of the disclosure, the transmission characteristic is measured using a reference photodiode or using a reference light source. A reference photodiode is understood to be a calibrated photodiode having known properties. A reference light source is understood to be a calibrated light source having known properties

For determining the transmission characteristic of an electro-optical conversion module, a known electrical signal is applied to the electro-optical conversion module, and an optical output signal of the conversion module is measured using the reference photodiode. The transmission characteristic of the conversion module can be determined from the known electrical signal and the measured optical signal.

For determining the transmission characteristic of an opto-electrical conversion module, a known optical signal is applied to the opto-electrical conversion module by means of the reference light source, and an electrical output signal of the conversion module is measured. The transmission characteristic of the conversion module can be determined from the known optical signal and the measured electrical signal.

According to a further embodiment of the disclosure, the actual S-parameters are determined based on error terms of the electrical transmission module and the electrical reception module. The accuracy of the determined actual S-parameters is further increased by taking the error terms into account.

Principally, the error terms can be determined using any suitable method known from the prior art, for example by means of the so-called UOSM method, also referred to as “UOSM calibration routine”

The error terms are for example determined based on a one-port model of the electrical transmission module and of the electrical reception module, which corresponds to an OSM method.

Alternatively or additionally, the error terms may be determined based on a two-port model of the electrical transmission module and of the electrical reception module, which corresponds to a UOSM method.

According to one aspect of the disclosure, the actual S-parameters of the electro-optical device are determined in accordance with

$$\begin{matrix}{S}_{11} = \frac{{S}_{11}^{m e a s} - {e}_{00}}{{e}_{01} {e}_{10} + {e}_{11} \cdot ( {S}_{11}^{m e a s} - {e}_{00} )} \\ {S}_{21} = \frac{- {S}_{21}^{m e a s} {e}_{01} {e}_{45}}{{e}_{32} \cdot ( {e}_{11} \cdot ( {S}_{11}^{m e a s} - {e}_{00} ) + {e}_{01} {e}_{10} ) \cdot ( {e}_{44} \cdot ( {S}_{22}^{m e a s} - {e}_{55} ) + {e}_{45} {e}_{54} )}\end{matrix}$$

wherein s₁₁^{meas} and s₂₁^{meas} are measured S-parameters of the electro-optical device, wherein s₂₂^{meas} is a measured S-parameter of the conversion module, and wherein the eᵢⱼ are error terms of the electrical transmission module and the electrical reception module. This will be explained in more detail below.

According to a further aspect of the disclosure, the actual S-parameters of the opto-electrical device are determined in accordance with

$$\begin{matrix}{S}_{21} = \frac{{S}_{21}^{m e a s} {e}_{01} {e}_{45}}{{e}_{32} \cdot ( {e}_{11} \cdot ( {S}_{11}^{m e a s} - {e}_{00} ) + {e}_{01} {e}_{10} ) \cdot ( {e}_{44} ( {S}_{22}^{m e a s} - {e}_{55} ) + {e}_{45} {e}_{54} )} \\ {S}_{22} = \frac{{S}_{22}^{m e a s} - {e}_{55}}{{e}_{45} {e}_{54} + {e}_{44} \cdot ( {S}_{22}^{m e a s} - {e}_{55} )}\end{matrix}$$

wherein s₂₁^{meas} and s₂₂^{meas} are measured S-parameters of the opto-electrical device, wherein s₁₁^{meas} is a measured S-parameter of the conversion module (14), and wherein the et are error terms of the electrical transmission module and the electrical reception module. This will be explained in more detail below.

According to the disclosure, the object is further achieved by a measurement system for measurements on an electro-optical device which is set up to convert electrical signals into optical signals, or on an opto-electrical device which is set up to convert optical signals into electrical signals. The measurement system includes a conversion module, wherein the conversion module is set up to convert optical signals into electrical signals, or electrical signals into optical signals. The measurement system further includes an electrical transmission module and an electrical reception module. The measurement system further includes a control module, wherein the control module is set up to cause the measurement system to carry out a calibration method as described above.

With regard to the further advantages and features of the measurement system, reference is made to the above explanations as to the calibration method, which also apply to the measurement system and vice versa.

In one embodiment of the disclosure, the electrical transmission module and the electrical reception module are integrated in a measurement instrument, in particular a vector network analyzer.

However, the electrical transmission module and/or the electrical reception module may also be integrated in any other suitable type of measurement instrument.

The conversion module is in particular configured separately from the measurement instrument.

It is however also conceivable that the conversion module is integrated in the measurement instrument.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 shows a measurement system according to the disclosure and according to a first embodiment;

FIG. 2 shows a measurement system according to the disclosure and according to a second embodiment;

FIG. 3 shows a flow diagram of a calibration method according to the disclosure;

FIG. 4 shows a diagram for illustrating the calibration method according to the disclosure for measurements on an electro-optical device; and

FIG. 5 shows a diagram for illustrating the calibration method according to the disclosure for measurements on an opto-electrical device.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

For the purposes of the present disclosure, the phrase “at least one of A, B, and C”, for example, means (A), (B), (C), (A and B), (A and C), (B and C), or (A, B, and C), including all further possible permutations when more than three elements are listed. In other words, the term “at least one of A and B” generally means “A and/or B”, namely “A” alone, “B” alone or “A and B”.

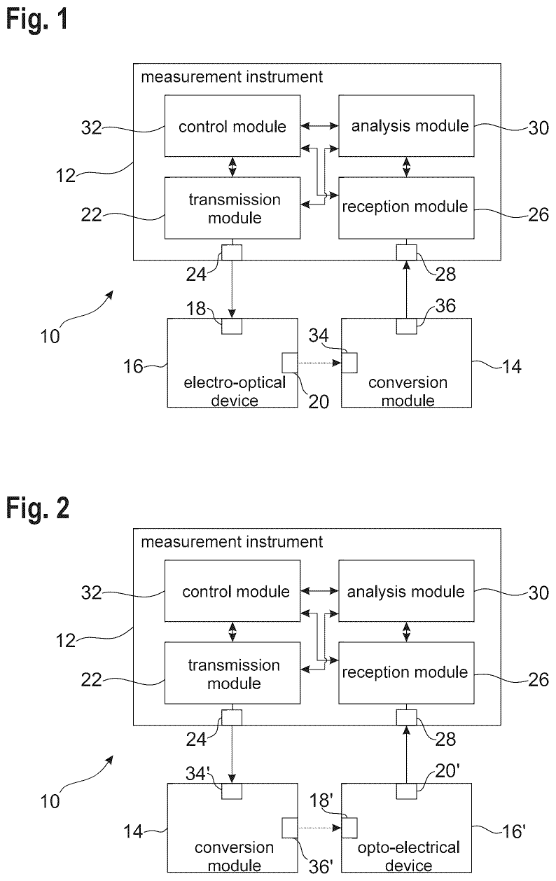

FIG. 1 schematically shows a measurement system 10 comprising a measurement instrument 12, a conversion module 14 and an electro-optical device 16. In general, the electro-optical device 16 is set up to convert electrical signals into optical signals. For example, the electro-optical device 16 may be an electro-optical converter used in data networks to convert electrical data signals into optical data signals. Accordingly, the electro-optical device 16 has an electrical input 18 and an optical output 20.

The electrical input 18 is set up to receive electrical signals. The electrical signals are converted by the electro-optical device 16 into optical signals, which are output via the optical output 20. It should be noted that in FIG. 1, electrical signals are shown with solid arrows, while optical signals are shown with dotted arrows.

In general, the measurement instrument 12 in conjunction with the conversion module 14 is set up to perform measurements on the electro-optical device 16 to test the operational behavior of the electro-optical device 16.

In the example embodiment shown in FIG. 1, the conversion module 14 is designed separately from the measurement instrument 12. However, it is also conceivable that the conversion module 14 is integrated in the measurement instrument 12.

For example, the measurement instrument 12 is configured as a vector network analyzer. However, the measurement instrument 12 can also be configured as any other suitable type of measurement instrument.

The measurement instrument 12 includes a transmission module 22, which is connected to an electrical output 24 of the measurement instrument 12. The measurement instrument 12 further includes a reception module 26, which is connected to an electrical input 28 of the measurement instrument 12. Furthermore, the measurement instrument comprises an analysis module 30 and a control module 32, the functionality of which is explained in more detail below.

In general, the conversion module 14 is set up to convert optical signals into electrical signals. For example, the conversion module 14 comprises a photodetector, in particular a photodiode, which is set up to convert optical signals into electrical signals. Accordingly, the conversion module 14 has an optical input 34 and an electrical output 36.

The optical input 34 is set up to receive optical signals. The optical input 34 of the conversion module 14 is connected to the optical output 20 of the electro-optical device 16, so that the conversion module 14 receives optical signals output by the electro-optical device 16. The optical signals are converted by the conversion module 14 into electrical signals, which are output via the electrical output 36. The electrical output 16 of the conversion module 14 is connected to the electrical input 28 of the measurement instrument 12, so that the reception module 26 receives the electrical signals output by the conversion module 14 via the electrical input 28.

FIG. 2 shows a further exemplary embodiment of the measurement system 10, only the differences to the embodiment described above with regard to FIG. 1 being explained below. The device under test here is an opto-electrical device 16′. For example, the opto-electrical device 16′ may be an opto-electrical converter used in data networks to convert optical data signals into electrical data signals. Accordingly, the opto-electrical device 16′ has an optical input 18′ and an electrical output 20′.

The conversion module 14 is set up to convert electrical signals into optical signals. For example, the conversion module 14 comprises a light source, in particular a laser, and a modulator, in particular a Mach-Zehnder modulator, which is set up to modulate the electrical signal onto the light emitted by the light source. Accordingly, the conversion module 14 has an electrical input 34′ and an optical output 36′.

The electrical input 34′ of the conversion module 14 is connected to the electrical output 24 of the measurement instrument 12. The optical input 18′ of the opto-electrical device 16′ is connected to the optical output 36′ of the conversion module 14. The electrical output 20′ of the opto-electrical device 16′ is connected to the electrical input 28 of the measurement instrument 12.

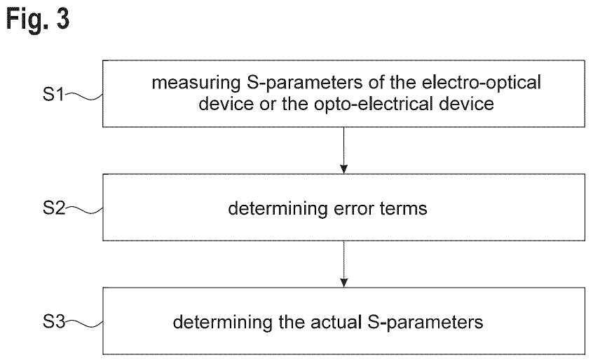

The measurement system 10 is set up to perform a calibration method, an example of which is described below with reference to FIG. 3.

More precisely, the control module 32 is set up to cause the measurement system 10 to perform the calibration method described below.

The method is first explained for the example embodiment shown in FIG. 1, i.e. for measurements on the electro-optical device 16.

Scattering parameters (S-parameters) of the electro-optical device 16 are measured, in particular using the analysis module 30 (step S1).

The measured S-parameters comprise a transmission coefficient s₂₁^{meas} in forward direction of the electro-optical device 16, a reflection coefficient s₁₁^{meas} of the electro-opticla device 16 in the electrical range (i.e. a reflection coefficient at the electrical input 18), and a reflection coefficient s₂₂^{meas} of the conversion module 14 in the electrical range (i.e. of the electrical output 36).

Predefined error terms of the electrical transmission module 22, the electrical reception module 26 and the conversion module 14 are determined, in particular using the analysis module 30 (step S2).

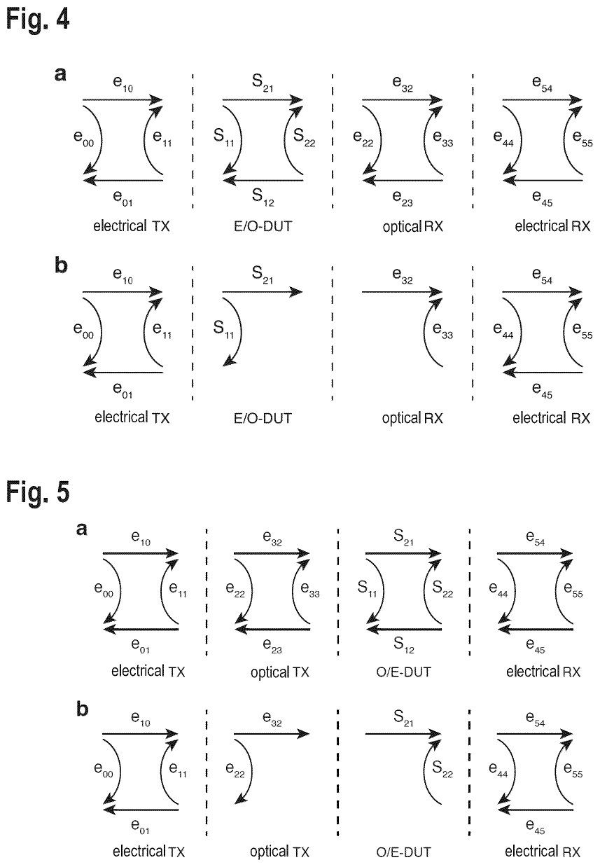

The error terms are illustrated in FIG. 4.

“Electrical TX” denotes the transmission module 22, “E/O-DUT” denotes

the electro-optical device 16 to be tested, “optical RX” denotes the conversion module 14, and “electrical RX” denotes the reception module 26.

The upper row marked “a” in FIG. 4 shows all error terms and the S-parameters of the electro-optical device 16. More precisely, e₁₀ describes a transmission characteristic of the transmission module 22 in forward direction, e₀₁ describes a transmission characteristic of the transmission module 22 in reverse direction, e₀₀ describes a reflection coefficient at the input of the transmission module 22, and e₁₁ describes a reflection coefficient at the output of the transmission module 22.

e₃₂ describes a transmission characteristic of the conversion module 14 in forward direction, e₂₃ describes a transmission characteristic of conversion module 14 in reverse direction, e₂₂ describes a reflection coefficient at the optical input 34 of the conversion module 14 (i.e. a reflection coefficient in the optical range), and e₃₃ describes a reflection coefficient at the electrical output 36 of the conversion module 14 (i.e. a reflection coefficient in the electrical range).

e₅₄ describes a transmission characteristic of the reception module 26 in forward direction, e₄₅ describes a transmission characteristic of the reception module 26 in reverse direction, e₄₄ describes a reflection coefficient at the input of the reception module 26, and e₅₅ describes a reflection coefficient at the output of the reception module 26.

The lower row marked “b” in FIG. 4 shows simplifications which are assumed for the further steps of the calibration method.

It is assumed that converting components, i.e. the conversion module 14 and the electro-optical device 16, only allow a forward transmission. This corresponds to the assumption S₁₂=e₂₃=0.

It is furthermore assumed that the actual reflection coefficients of the conversion module 14 and/or the electro-optical device 16 in the optical range are zero. This corresponds to the assumption S₂₂=0 and/or e₂₂=0.

For example, the described calibration method thus provides reliable results, even if the matching S₂₂ of the electro-optical device 16 in the optical range is not perfect, as long as the matching e₂₂ of the conversion module 14 is perfect.

Furthermore, the calibration method provides reliable results even if the matching e₂₂ of the conversion module 14 in the optical range is not perfect, as long as the matching S₂₂ of the electro-optical device 16 is perfect.

The transmission characteristic e₃₂ of the conversion module 14 is usually independent of the test setup. It is therefore conceivable that the transmission characteristic e₃₂ is determined by the manufacturer, for example in the context of a calibration of the conversion module 14 during manufacture.

The transmission characteristic e₃₂ can accordingly be stored in a data storage device of the measurement system 10, in particular of the conversion module 14, and can be used without additional effort for calibrating the measurement system 10. It is however also possible for the transmission characteristic e₃₂ to be determined, in particular re-determined by a user of the measurement system 10.

For determining the transmission characteristic e₃₂ of the electro-optical conversion module 14, a known electrical signal is for example applied to the electro-optical conversion module 14, and an optical output signal of the conversion module 14 is measured using a reference photodiode. The transmission characteristic e₃₂ of the conversion module 14 can be determined from the known electrical signal and the measured optical signal.

The error terms e₀₀, e₁₀, e₀₁, e₁₁, e₄₄, e₄₅, e₅₄ and e₅₅ can in principle be determined using any suitable method known from the prior art, for example using the so-called UOSM method, also referred to as “UOSM calibration routine”.

In particular, these error terms are determined based on a one-port model (corresponds to an OSM method) or based on a two-port model (corresponds to a UOSM method) of the electrical transmission module 22 and the electrical reception module 26.

The source port matching e₃₃ of the conversion module 14 can be determined from the measured S-parameter s₂₂^{meas} and the other error terms by rearranging the equation below:

$${S}_{22}^{m e a s} = \frac{{e}_{33} \cdot ( {e}_{45} {e}_{54} - {e}_{44} {e}_{55} )}{1 - {e}_{33} {e}_{44}} .$$

Actual S-parameters of the electro-optical device 16 are determined based on the measured S-parameters and based on the determined error terms, in particular by means of the analysis module 30 (step S3).

More precisely, the S-parameters are determined in accordance with the equations below:

$$\begin{matrix}{S}_{11} = \frac{{S}_{11}^{m e a s} - {e}_{00}}{{e}_{01} {e}_{10} + {e}_{11} \cdot ( {S}_{11}^{m e a s} - {e}_{00} )} \\ {S}_{21} = \frac{- {S}_{21}^{m e a s} {e}_{01} {e}_{45}}{{e}_{32} \cdot ( {e}_{11} \cdot ( {S}_{I I}^{m e a s} - {e}_{00} ) + {e}_{01} {e}_{10} ) \cdot ( {e}_{44} \cdot ( {S}_{22}^{m e a s} - {e}_{55} ) + {e}_{45} {e}_{54} )}\end{matrix} .$$

Due to the simplifying assumptions described above, the described calibration method permits a fast and resource-saving determination of the actual S-parameters S₁₁ and S₂₁ of the electro-optical device 16.

Due to the consideration of the non-zero source port matching e₃₃ of the conversion module 14, the described calibration method furthermore permits a particularly accurate determination of the actual S-parameters S₁₁ and S₂₁ of the electro-optical device 16.

The method described above can also be applied, with the modifications described below, to measurements on the opto-electrical device 16′ shown in FIG. 2. Only the differences to the calibration method described above will be explained below.

The upper row marked “a” in FIG. 5 illustrates all error terms and the S-parameters of the opto-electrical device 16′. The S-parameters measured in step S1 comprise here a transmission coefficient s₂₁^{meas} in forward direction of the opto-electrical device 16′, a reflection coefficient s₁₁^{meas} as of the conversion module 14 in the electrical range (i.e. at the electrical input 34′), and a reflection coefficient s₂₂^{meas} as of the opto-electrical device 16′ in the electrical range (i.e. a reflection coefficient at the electrical output 20′). The lower row marked “b” in FIG. 5 shows the simplifications made for the calibration method.

It is assumed that converting components, i.e. the conversion module 14 and the opto-electrical device 16′, only allow a forward transmission. This corresponds to the assumption S₁₂=e₂₃=0.

It is furthermore assumed that the actual reflection coefficients of the conversion module 14 and/or the opto-electrical device 16′ in the optical range are zero. This corresponds to the assumption S₁₁=0 an/or e₃₃=0.

For example, the calibration method described thus provides reliable results, even if the matching S₁₁ of the opto-electrical device 16′ in the optical range is not perfect, as long as the matching e₃₃ of the conversion module 14 is perfect.

Furthermore, the calibration method provides reliable results even if the matching e₃₃ of the conversion module 14 in the optical range is not perfect, as long as the matching S₁₁ of the opto-electrical device 16′ is perfect.

For determining the transmission characteristic e₃₂ of the opto-electrical conversion module 14, a known optical signal is applied to the conversion module 14 by means of a reference light source, and an electrical output signal of the conversion module 14 is measured. The transmission characteristic e₃₂ of the conversion module 14 can be determined from the known optical signal and the measured electrical signal.

In principle, the remaining error terms can be determined using any suitable method known from the prior art, for example using the so-called UOSM method, also referred to as “UOSM calibration routine”.

In particular, these error terms are determined based on a one-port model (corresponds to an OSM method) or based on a two-port model (corresponds to a UOSM method) of the electrical transmission module 22 and the electrical reception module 26.

The directivity e₂₂ of the conversion module 14 can be determined from the measured S-parameter smeds and from the other error terms by rearranging the equation below:

$${S}_{11}^{m e a s} = \frac{{e}_{22} \cdot ( {e}_{01} {e}_{10} - {e}_{00} {e}_{11} )}{1 - {e}_{11} {e}_{22}} .$$

The actual S-parameters are determined in accordance with the equations below:

$$\begin{matrix}{S}_{21} = \frac{{S}_{21}^{m e a s} {e}_{01} {e}_{45}}{{e}_{32} \cdot ( {e}_{11} \cdot ( {S}_{11}^{m e a s} - {e}_{00} ) + {e}_{01} {e}_{10} ) \cdot ( {e}_{44} ( {S}_{22}^{m e a s} - {e}_{55} ) + {e}_{45} {e}_{54} )} \\ {S}_{22} = \frac{{S}_{22}^{m e a s} - {e}_{55}}{{e}_{45} {e}_{54} + {e}_{44} \cdot ( {S}_{22}^{m e a s} - {e}_{55} )} .\end{matrix}$$

Certain embodiments disclosed herein, particularly the respective module(s) and/or unit(s), utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes one or more processors or portions thereof and accompanying software, firmware, hardware, and the like.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about”, “approximately”, “near” etc., mean plus or minus 5% of the stated value.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A calibration method for calibrating a measurement system for measurements on an electro-optical device which is set up to convert electrical signals into optical signals, or on an opto-electrical device which is set up to convert optical signals into electrical signals,
wherein the measurement system includes a conversion module, wherein the conversion module is set up to convert optical signals into electrical signals, or electrical signals into optical signals, and
wherein the measurement system further includes an electrical transmission module and an electrical reception module,
wherein the calibration method comprises:
measuring scattering parameters (S-parameters) of the electro-optical device or the opto-electrical device, wherein the measured S-parameters comprise at least one transmission coefficient in forward direction and two reflection coefficients; and
determining actual S-parameters of the electro-optical device or the opto-electrical device based on the measured S-parameters;
wherein the actual S-parameters are determined based on a non-zero electrical output or input matching of the conversion module,
wherein for the determination of the actual S-parameters, it is assumed that converting components only allow a forward transmission, and
wherein for the determination of the actual S-parameters, it is further assumed that an actual reflection coefficient of the electro-optical device or the opto-electrical device in the optical range is equal to zero, and/or that an actual reflection coefficient of the conversion module in the optical range is equal to zero.

2. The calibration method according to claim 1, wherein the actual S-parameters are determined based on a transmission characteristic of the conversion module.

3. The calibration method according to claim 2, wherein the transmission characteristic is measured using a reference photodiode or using a reference light source.

4. The calibration method according to claim 1, wherein the actual S-parameters are determined based on error terms of the electrical transmission module and the electrical reception module.

5. The calibration method according to claim 4, wherein the error terms are determined based on a one-port model of the electrical transmission module and the electrical reception module.

6. The calibration method according to claim 4, wherein the error terms are determined based on a two-port model of the electrical transmission module and the electrical reception module.

7. The calibration method according to claim 1, wherein the actual S-parameters of the electro-optical device are determined in accordance with
$$\begin{matrix}{S}_{11} = \frac{{S}_{11}^{m e a s} - {e}_{00}}{{e}_{01} {e}_{10} + {e}_{11} \cdot ( {S}_{11}^{m e a s} - {e}_{00} )} \\ {S}_{21} = \frac{- {S}_{21}^{m e a s} {e}_{01} {e}_{45}}{{e}_{32} \cdot ( {e}_{11} \cdot ( {S}_{11}^{m e a s} - {e}_{00} ) + {e}_{01} {e}_{10} ) \cdot ( {e}_{44} \cdot ( {S}_{22}^{m e a s} - {e}_{55} ) + {e}_{45} {e}_{54} )}\end{matrix}$$
wherein s₁₁^{meas} and s₂₁^{meas} are measured S-parameters of the electro-optical device, wherein s₂₂^{meas} is a measured S-parameter of the conversion module, and wherein the eᵢⱼ are error terms of the electrical transmission module and the electrical reception module.

8. The calibration method according to claim 1, wherein the actual S-parameters of the opto-electrical device are determined in accordance with
$$\begin{matrix}{S}_{21} = \frac{{S}_{21}^{m e a s} {e}_{01} {e}_{45}}{{e}_{32} \cdot ( {e}_{11} \cdot ( {S}_{11}^{m e a s} - {e}_{00} ) + {e}_{01} {e}_{10} ) \cdot ( {e}_{44} ( {S}_{22}^{m e a s} - {e}_{55} ) + {e}_{45} {e}_{54} )} \\ {S}_{22} = \frac{{S}_{22}^{m e a s} - {e}_{55}}{{e}_{45} {e}_{54} + {e}_{44} \cdot ( {S}_{22}^{m e a s} - {e}_{55} )}\end{matrix}$$
wherein s₂₁^{meas} and s₂₂^{meas} are measured S-parameters of the opto-electrical device, wherein s₁₁^{meas} is a measured S-parameter of the conversion module, and wherein the eᵢⱼ are error terms of the electrical transmission module and the electrical reception module.

9. A measurement system for measurements on an electro-optical device which is set up to convert electrical signals into optical signals, or on an opto-electrical device which is set up to convert optical signals into electrical signals,
wherein the measurement system includes a conversion module, wherein the conversion module is set up to convert optical signals into electrical signals, or electrical signals into optical signals,
wherein the measurement system further includes an electrical transmission module and an electrical reception module,
wherein the measurement system includes a control module, and
wherein the control module is set up to cause the measurement system to carry out a calibration method according to claim 8.

10. The measurement system according to claim 9, wherein the electrical transmission module and the electrical reception module are integrated in a measurement instrument.

11. The measurement system according to claim 9, wherein the electrical transmission module and the electrical reception module are integrated in a vector network analyzer.
